(19) United States
(12) Patent Application Publication
(10) Pub. No.: US 2026/0047138 A1
(43) Pub. Date: Feb. 12, 2026

(54) SQUARED SHEET GATE-ALL-AROUND TRANSISTORS WITH NON-UNIFORM GATE INSULATORS

(71) Applicant: Taiwan Semiconductor Manufacturing Company, Ltd., Hsin-Chu (TW)

(72) Inventors: Chun-Yen Peng, Hsinchu (TW); Hsueh-Ju Chen, Taipei City (TW); Tsung-Da Lin, Hsinchu (TW); Chi On Chui, Hsinchu City (TW)

(21) Appl. No.: 18/799,672

(22) Filed: Aug. 9, 2024

(51) Int. Cl. H01L 29/423; H01L 21/324; H01L 21/8238; H01L 27/092; H01L 29/06; H01L 29/66; H01L 29/775; H01L 29/786

(52) U.S. Cl. CPC H10D 30/6735; H01L 21/324; H10D 30/014; H10D 30/43; H10D 30/6757; H10D 62/121; H10D 84/0167; H10D 84/017; H10D 84/038; H10D 84/85

(57) ABSTRACT

One aspect of the present disclosure pertains to a method. The method forms a stack of semiconductor channels over a semiconductor fin. Each of the semiconductor channels are squared-shaped with rounded corners, and the rounded corners interface between vertical and horizontal surfaces of the semiconductor channels. The method forms a nonconformal interfacial layer over and wrapping around each semiconductor channel of the stack of semiconductor channels. The interfacial layer has a thicker portion at corner portions of the semiconductor channels and a thinner portion at non-corner portions of the semiconductor channels. The method forms a nonconformal high-k dielectric layer over and wrapping around the nonconformal interfacial layer. The high-k dielectric layer has a thicker portion on the thicker portion of the interfacial layer and a thinner portion on the thinner portion of the of the interfacial layer. The method forms a gate electrode over the high-k dielectric layer.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

One advancement is in the development of gate-all-around (GAA) field effect transistors (FETs). GAA FETs refer to transistors having gate stacks (gate electrodes and gate dielectric layers) surrounding transistor channels, such as vertically-stacked gate-all-around horizontal nanowire or nanosheet MOSFET devices. The nanowire or nanosheet transistor channels are typically formed with circular, oval, or rounded square profiles with greater than 50% curvature portions at its channel sidewalls. However, the high curvature at channel sidewalls induces local extraneous electric fields that limit and degrade reliability lifetime of the transistor devices. Further, these transistor channels are typically surrounded by conformal and uniform gate insulators. The gate insulators conform to the curved shape at the corners of the channels. As such, the gate insulators are limited in addressing the extraneous electric field effects caused by the channel curvature.

Therefore, although existing GAA FETs with nanosheet channels have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a flow chart of a method to form a semiconductor device having square-shaped channels with thicker gate dielectric insulators at its channel corners, in portion or in entirety, according to an embodiment of the present disclosure.

FIG. 2 illustrates a three-dimensional view of a semiconductor workpiece and with lines A-A′, B-B′, and C-C′ cut across the workpiece.

FIGS. 3A, 4A, 5A, 6A, 7A, 8A, 9A, 10A, 11A, 12A, and 13A illustrate cross-sectional views of a semiconductor device cut along the lines A-A′ in FIG. 2 at intermediate stages of fabrication and processed in accordance with the method of FIG. 1 according to an embodiment of the present disclosure.

FIGS. 3B, 4B, 5B, 6B, 7B, 8B, 9B, 10B, 11B, 12B, and 13B illustrate cross-sectional views of a semiconductor device cut along the lines B-B′ in FIG. 2 at intermediate stages of fabrication and processed in accordance with the method of FIG. 1 according to an embodiment of the present disclosure.

FIGS. 3C, 4C, 5C, 6C, 7C, 8C, 9C, 10C, 11C, 12C, and 13C illustrate cross-sectional views of a semiconductor device cut along the lines C-C′ in FIG. 2 at intermediate stages of fabrication and processed in accordance with the method of FIG. 1 according to an embodiment of the present disclosure.

FIGS. 14A and 14B illustrate semiconductor devices having square-shaped channels, according to different embodiments of the present disclosure.

FIGS. 15A and 15B illustrate blown up views of FIGS. 14A and 14B to illustrate further dimension details of the semiconductor devices of FIGS. 14A and 14B, respectively.

FIG. 16 illustrates a flow chart of a method to form metal gate structures with thicker gate dielectric insulators at transistor channel corners, in portion or in entirety, according to an embodiment of the present disclosure.

FIG. 17 illustrates a semiconductor device having a first and a second GAA device, according to an embodiment of the present disclosure.

FIG. 18 illustrates a semiconductor device having a first and a second GAA device, according to another embodiment of the present disclosure.

FIG. 19 illustrates a semiconductor device having a first and a second GAA device, according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to gate-all-around (GAA) field effect transistors (FETs) having square-shaped channels with thicker gate dielectric insulators at its channel corners. The squared-shaped channels are defined by channels that have sidewalls with more flat vertical portions than curved portions. In other words, each sidewall of the channels are formed to have less than 50% curvature portions at its channel sidewalls. By reducing channel sidewall curvature, local extraneous electric fields caused by curved channel surfaces are minimized, thereby improving reliability and performance of the transistor devices. Further, a squared sheet channel shape is beneficial to higher drive current (Iₒₙ), lower current leakage (I_{off}), and better reliability lifetime. However, due to process limitations, there still remains sharper curved portions at the corners of the squared-shaped channels (i.e., rounded corners). As such, extraneous electric fields may still be induced and propagate outward at the channel corners. The present disclosure addresses this by forming nonconformal gate dielectric layers that have thicker portions surrounding channel corners for gate oxide reliability boost. With thicker gate dielectric insulators at channel corners, the concern of local electric field enhancement caused by sharper curvature at channel corners can be compensated.

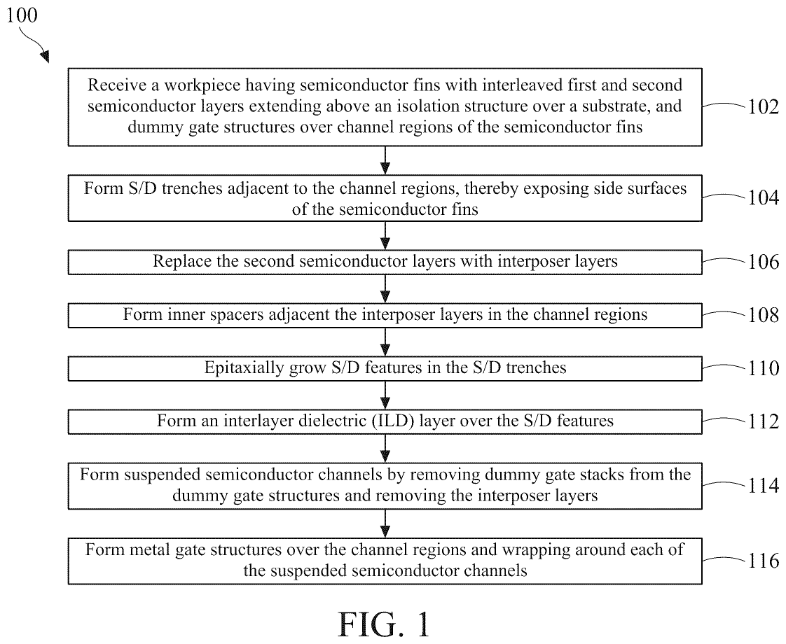

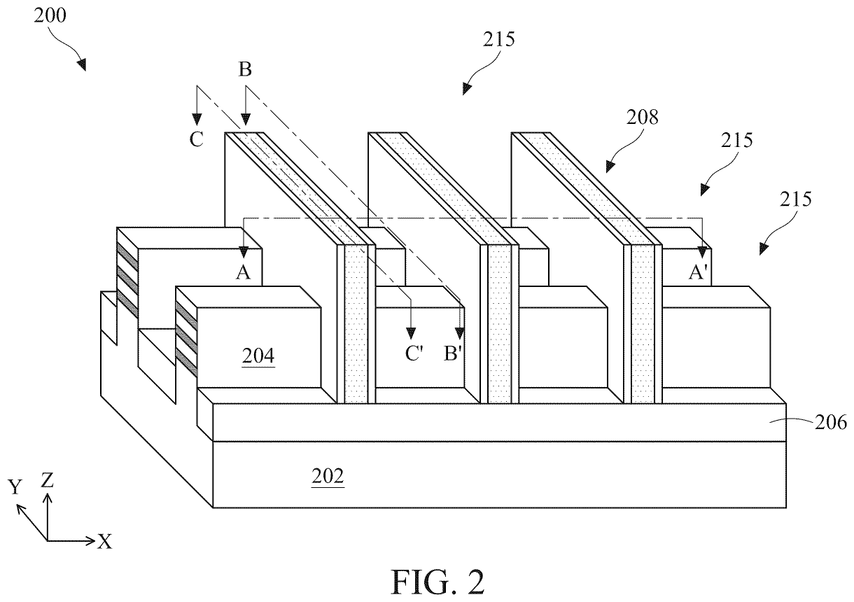

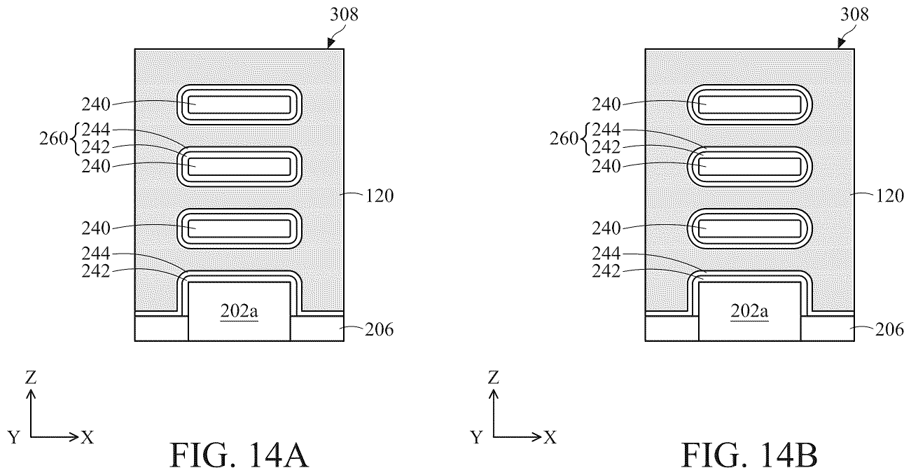

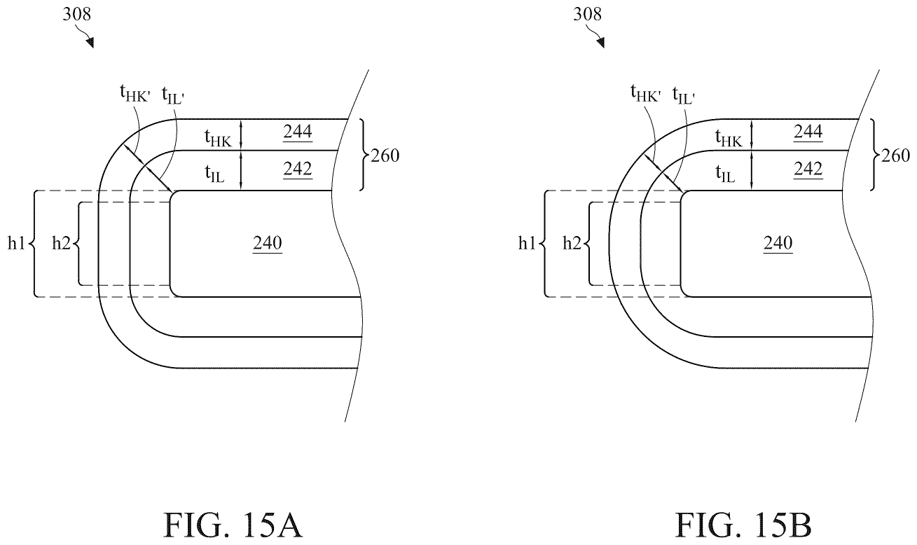

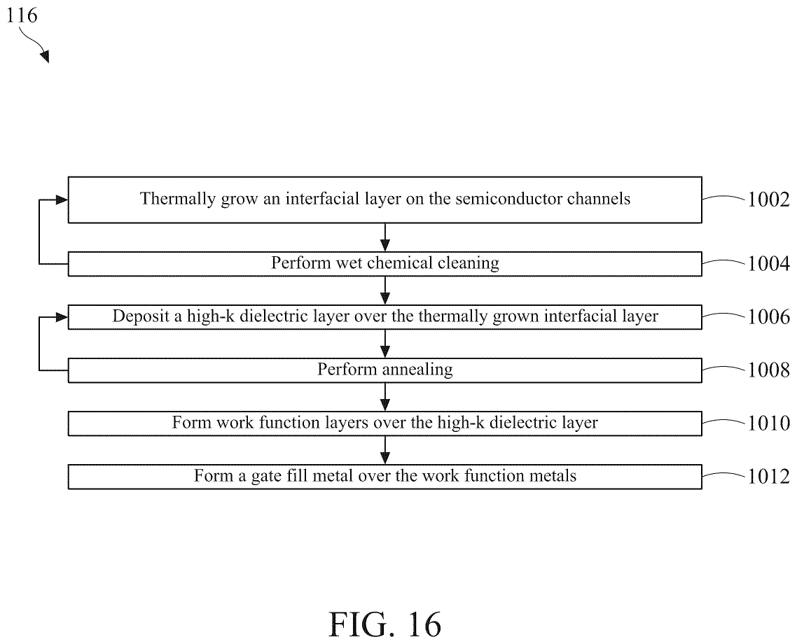

FIG. 1 illustrates a flow chart of a method 100 to form a semiconductor device 200 having square-shaped channels with thicker gate dielectric insulators at its channel corners, in portion or in entirety, according to an embodiment of the present disclosure. Note that further details about forming thicker gate dielectric insulators are expanded in the flowchart of FIG. 16, which expands upon an operation step of the method 100. The method 100 is described below with reference to FIGS. 2, 3A-13A, 3B-13B, and 3C-13C, and with further details described with reference to FIGS. 14A-15A, and 14A-15B. These figures have been simplified for the sake of clarity to better understand the inventive concepts of the present disclosure. Additional features can be added in the semiconductor device 200, and some of the features described below can be replaced, modified, or eliminated in other embodiments of the semiconductor device 200.

The semiconductor device 200 described herein may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

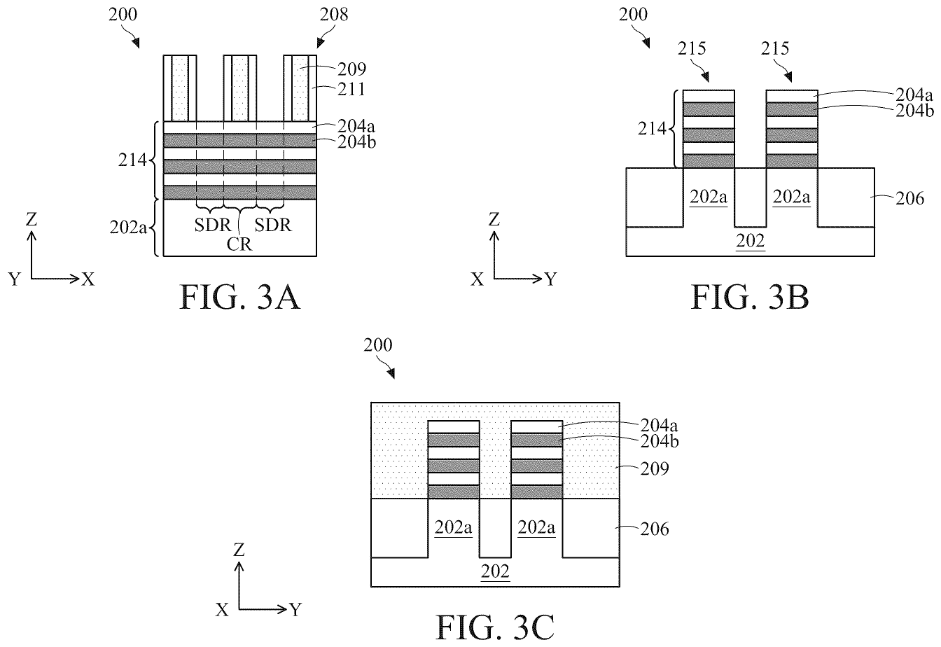

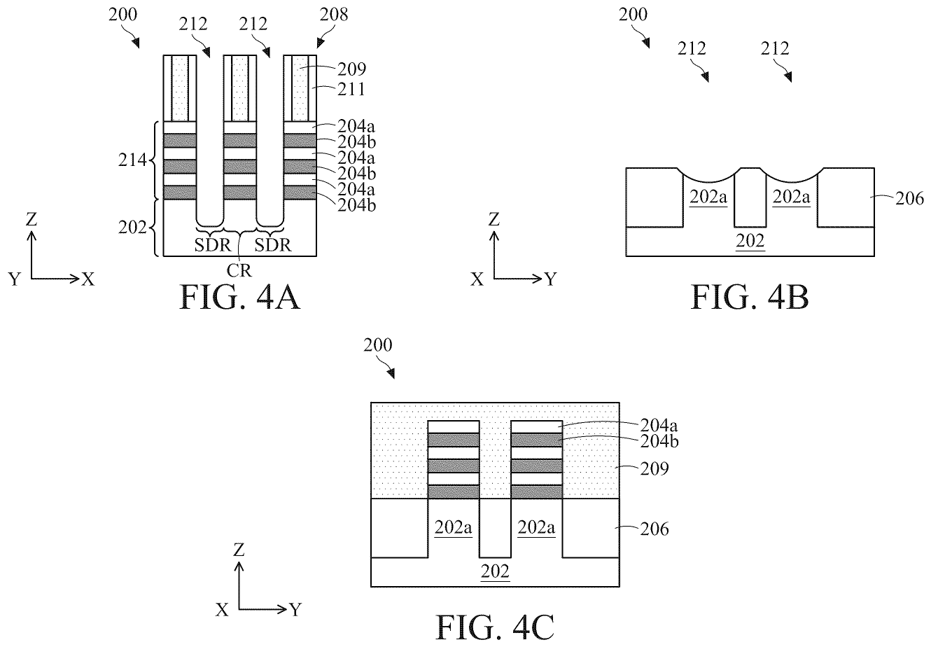

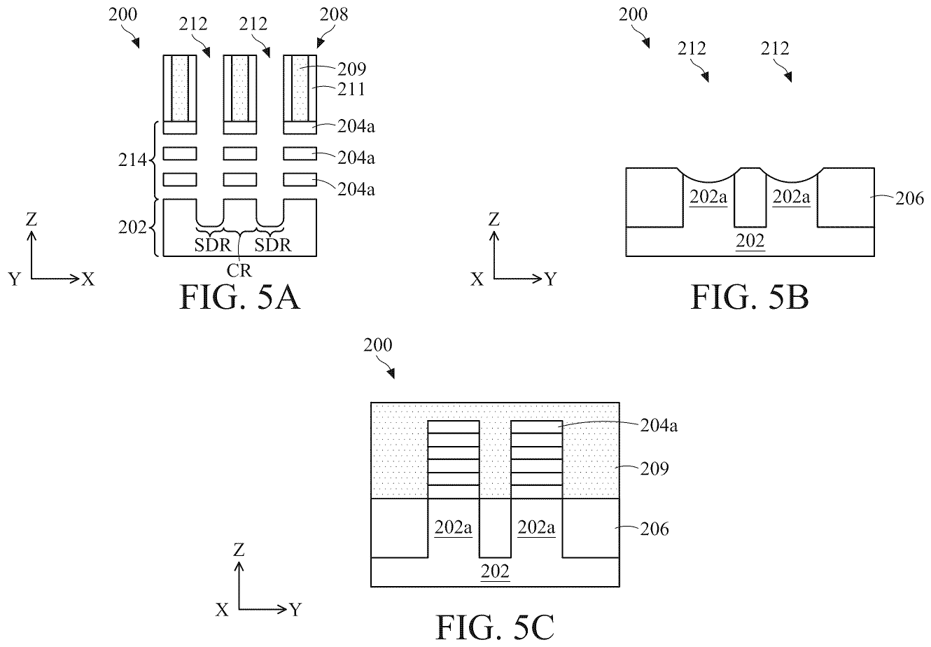

FIG. 2 illustrates a three-dimensional view of a semiconductor workpiece 250 and with lines A-A′, B-B′, and C-C′ cut across the workpiece 250. The semiconductor workpiece 250 corresponds to a semiconductor device 200 at the beginning of method 100. The line A-A′ cuts lengthwise in the x direction along a semiconductor fin 215 and across multiple dummy gate structures 208. The line B-B′ cuts lengthwise in the y direction across multiple source/drain regions (SDR) of the semiconductor fins 215. The line C-C′ cuts lengthwise in the y direction across a dummy gate stack 209 of a dummy gate structure 208. FIGS. 3A-13A, 3B-13B, and 3C-13C illustrate cross-sectional views of a semiconductor device 200 cut along the lines A-A′, B-B′, and C-C′ respectively at intermediate stages of fabrication and processed in accordance with the method 100 of FIG. 1. FIGS. 3A, 3B, and 3C are at a same stage of fabrication, FIGS. 4A, 4B, and 4C are at a same stage of fabrication, FIGS. 5A, 5B, and 5C are at a same stage of fabrication, and so on.

Referring now to FIG. 2 and FIGS. 3A-3C collectively, the method 100 at operation 102 receives a workpiece 250 having semiconductor fins 215 with interleaved first and second semiconductor layers 204a and 204b extending above an isolation structure 206 over a substrate 202. The workpiece 250 further includes dummy gate structures 208 over channel regions CR of the semiconductor fins 215.

The workpiece 250 may be formed by the following process. First, a substrate 202 is received. The substrate 202 may be a silicon (Si) substrate, or a substrate having other semiconductor materials such as germanium (Ge), silicon carbide (SiC), silicon germanium (SiGe), or diamond. The substrate 202 may be doped with a p-type dopant such as boron or an n-type dopant such as phosphorus. In a further embodiment, the substrate 202 may be doped with nitrogen for growing defect-free silicon crystal stacks (e.g., semiconductor stack 204) or defect-free silicon crystal source/drain features (e.g., source/drain features 800 later described).

Thereafter, a semiconductor stack 204 is formed over the substrate 202. In an embodiment, the semiconductor stack 204 is epitaxially grown over the substrate 202. The semiconductor stack 204 includes interleaved first and second semiconductor layers 204a and 204b. The first semiconductor layers 204a have a different material composition than the second semiconductor layers 204b. For example, each of the first semiconductor layers 204a is made of silicon and each of the second semiconductor layers 204b is made of silicon germanium.

Thereafter, the semiconductor stacks 204 and the substrate 202 may be patterned to form semiconductor fins 215. Each of the semiconductor fins 215 includes a protruding portion 202a of the substrate 202 and a semiconductor stack portion 214 of the semiconductor stack 204. The semiconductor fins 215 may be formed by a patterning process that includes lithography and etching. In some embodiments, a lithography process forms a patterned mask layer that covers regions for forming the semiconductor fins 215, and an etching process uses the patterned mask layer as an etch mask to etch exposed portions of the patterned mask layer. The etching process forms recesses that separate and define the semiconductor fins 215.

Thereafter, an isolation layer for forming an isolation structure 206 may be deposited over the semiconductor fins. The isolation layer lands on a top surface of the substrate 202, fills in the recesses between the semiconductor fins 215, and lands on a top surface of the semiconductor fins 215. In other words, the isolation layer is overfilled to surround all exposed surfaces of the semiconductor fins 215. The isolation layer may be deposited by any suitable deposition process, and the isolation layer may include silicon oxide, silicon oxynitride, fluorine-doped silicate glass (FSG), a low-k dielectric, combinations thereof, and/or other suitable materials.

Thereafter, the isolation layer may be recessed to form the isolation structure 206 surrounding bottom portions (e.g., protruding portions 202a) of the semiconductor fins 215. The isolation structure 206 may be formed by first performing a Chemical Mechanical Polish (CMP) to remove excess portions of the isolation layer over top surfaces of the semiconductor fins 215. The remaining portions of the isolation layer form isolation regions laterally between semiconductor fins 215. Next, the isolation regions are recessed in an etching step, so that the semiconductor stack portions 214 of the semiconductor fins 215 are over the top surfaces of the isolation regions. The resulting isolation regions form the isolation structure 206. In the present embodiment, the isolation structure 206 is a shallow trench isolation (STI) structure.

Thereafter, dummy gate structures 208 having dummy gate stacks 209 and gate spacers 211 are formed over channel regions CR of the semiconductor fins 215. The semiconductor fins 215 (also referred to as active regions or fin active regions) extend lengthwise in the x direction, and the dummy gate structures 208 extend lengthwise in the y direction.

Referring to FIG. 3A, the channel regions CR are regions of the semiconductor fins 215 underneath the dummy gate structures 208. The source/drain (S/D) regions SDR are regions of the semiconductor fins 215 adjacent the channel regions CR and extending between the dummy gate structures 208. Each of the dummy gate structures 208 includes a dummy gate stack 209 and gate spacers 211 over sidewalls of the dummy gate stack 209. The dummy gate stack 209 may be made of polysilicon and the gate spacers 211 may be made of silicon oxide, silicon nitride, silicon oxycarbide, silicon oxycarbonitride, silicon carbonitride, metal nitride, or a suitable dielectric material. Referring to FIGS. 3B-3C, since the dummy gate structures 208 are disposed only over channel regions CR and not over the S/D regions SDR, only FIG. 3C shows a dummy gate stack 209 covering the semiconductor fins 215. Although not shown, the dummy gate stacks 209 may include various layers, such as dummy gate electrode layers, dummy gate dielectric layers, and/or dummy hard mask layers.

Referring now to FIGS. 4A-4C collectively, the method 100 at operation 104 forms S/D trenches 212 in the S/D regions SDR adjacent to the channel regions CR. The S/D trenches 212 expose side surfaces of remaining portions of the semiconductor fins 215 (i.e., portions in the channel regions CR). The S/D trenches 212 may be formed by a dry etching process, a wet etching process, other suitable etching process, or combinations thereof. In some embodiments, the etching process is a multi-step etch process. For example, the etching process may include alternative etchants to separately and alternately remove semiconductor layers 204a and semiconductor layers 204b. In some embodiments, parameters of the etching process are configured to selectively etch semiconductor stack portions 214 with minimal (to no) etching of dummy gate structures 208 (i.e., dummy gate stacks 209 and gate spacers 211). In some embodiments, a lithography process is performed to form a patterned mask layer that covers dummy gate structures 208, and the etching process uses the patterned mask layer as an etch mask when forming the S/D trenches 212. In the embodiment shown, the etching process may partially etch the isolation structure 206, causing some loss of the isolation structure 206.

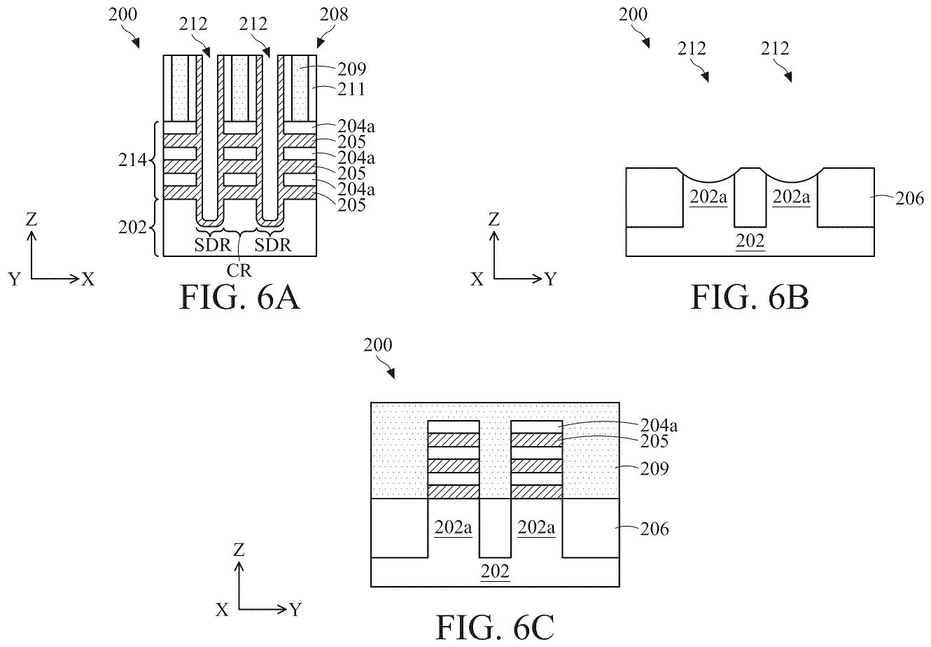

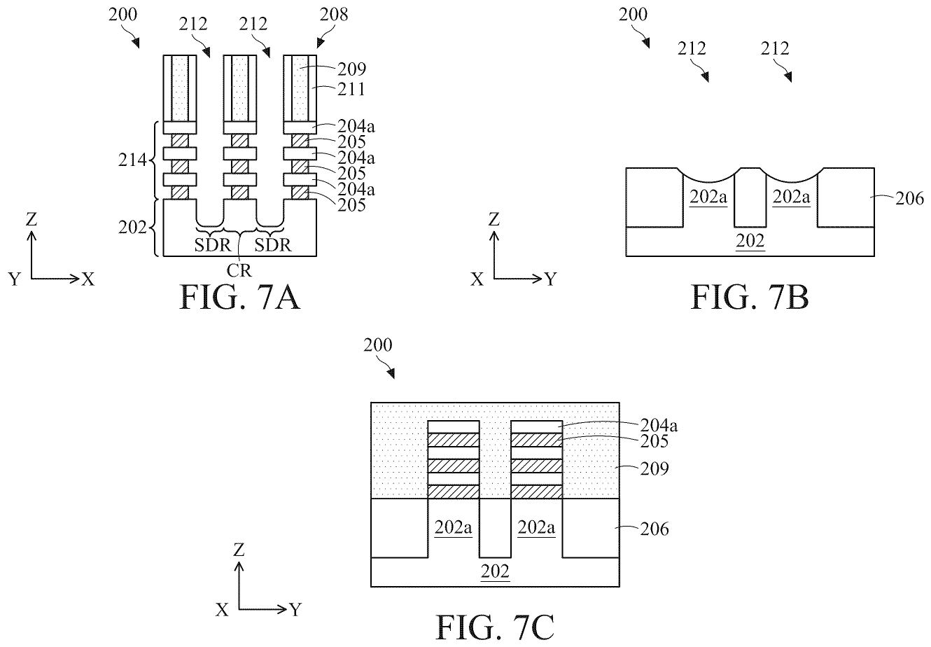

Referring now to FIGS. 5A-5C, 6A-6C, and 7A-7C collectively, the method 100 at operation 106 replaces the second semiconductor layers 204b with interposer layers 205. The operation 106 may include lateral etching to completely remove the second semiconductor layers 204b with minimal (to no) etching of the first semiconductor layers 204a (see FIG. 5A and FIG. 5C). For example, the etching includes high selectivity to etch SiGe as compared to etching Si. As a result, one or more of the first semiconductor layers 204a may be suspended in the vertical direction. Then, interposer layers 205 are formed in the space left behind by the removed second semiconductor layers 204b (see FIG. 6A and FIG. 6C). The interposer layers 205 may be formed by an interposer deposition process and an interposer etching process. For example, an interposer deposition process is performed to conformally fill a dielectric material in the S/D trenches 212. The dielectric material seeps into the gaps left behind by the removed second semiconductor layers 204b, thereby filling in the gaps. In the present embodiment, the dielectric material of the interposer layers 205 is an oxide-based dielectric such as silicon oxide. Then, an interposer etching process is performed to selectively etch the dielectric material to form the interposer layers 205 (see FIG. 7A). The interposer etching process may be a dry etching process to remove the excess dielectric material in the S/D trenches 212 and outside of the channel regions CR.

Further, and referring specifically to FIG. 7A, the interposer etching process may include a side etch process to selectively etch sidewalls of the interposer layers 205 without etching (or substantially etching) the first semiconductor layers 204a. In other words, the side etch process is configured to laterally etch (e.g., along the x direction) interposer layers 205, thereby reducing a length of the interposer layers 205 along the x direction. The side etch process is a dry etching process, a wet etching process, other suitable etching process, or combinations thereof. After the side etch process is performed, air gaps are formed under each of the first semiconductor layers 204a.

The interposer layers 205 will later be removed at a later channel-release stage when forming metal gates. Note that in some embodiments (not shown), the second semiconductor layers 204b are not replaced with the interposer layers 205. Instead, the second semiconductor layers 204b remain until they are removed at the later channel-release stage. In these embodiments, the resulting channels are more curved along its sidewalls (e.g., with greater than 50% curvature portions at its channel sidewalls). This is due to (in part) less optimal etchant selectivity when removing the second semiconductor layers 204b instead of the interposer layers 205 during channel release. For the present embodiments, by replacing the second semiconductor layers 204b with interposer layers 205, there will be reduced damage to the silicon channels and the S/D features during channel-release. As a result, the resulting channels are more square-shaped and are less curved along its sidewalls (e.g., with less than 50% curvature portions at its channel sidewalls). This is because (in part) the interposer layers 205 can be selectively and precisely removed with no or little semiconductor residue (e.g., no SiGe residue), as opposed to directly removing the second semiconductor layers 204b at the channel-release stage.

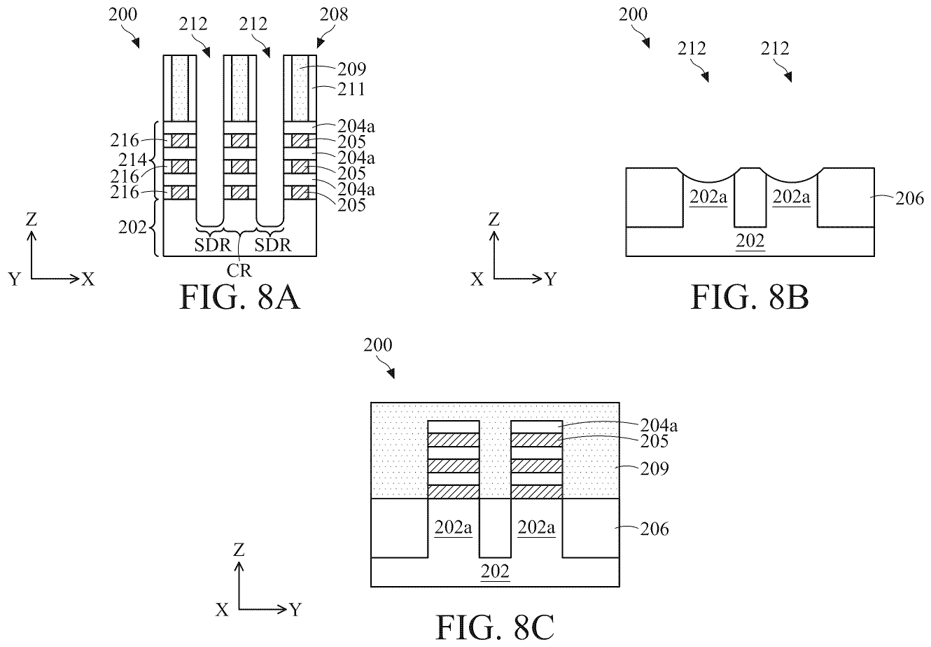

Referring now to FIGS. 8A-8C collectively, the method 100 at operation 108 forms inner spacers 216 adjacent to the interposer layers 205 in the channel regions CR. The inner spacers 216 are formed in the air gaps under each of the first semiconductor layers 204a. The inner spacers are disposed directly below the gate spacers 211, and they may be substantially vertically aligned with the gate spacers 211 along the z direction. The inner spacers 216 may be formed by any suitable process. In an embodiment, the inner spacers 216 may be formed by a spacer deposition process and a spacer etching process. For example, a spacer deposition process is performed to form a spacer layer over the dummy gate structures 208 and over features defining the S/D trenches 212 (e.g., semiconductor layers 204a, interposer layers 205, and substrate 202). The spacer layer partially (and, in some embodiments, completely) fills the S/D trenches 212. The spacer deposition process is configured to ensure that the spacer layer fills the air gaps between semiconductor layers 204a and between semiconductor layers 204a and substrate 202 under gate spacers 211. A spacer etching process is then performed that selectively etches the spacer layer to form inner spacers 216 as depicted in FIG. 8A with minimal (to no) etching of semiconductor layers 204a, dummy gate stacks 209, and gate spacers 211. The spacer layer (and thus inner spacers 216) includes a material that is different than a material of semiconductor layers 204a and a material of gate spacers 211 to achieve desired etching selectivity. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material.

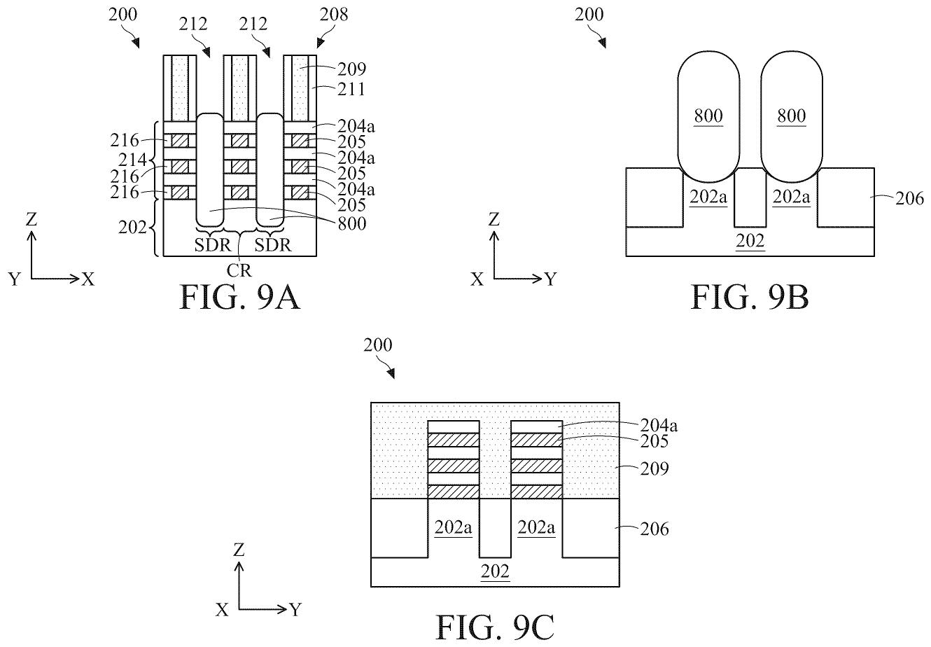

Referring now to FIGS. 9A-9C collectively, the method 100 at operation 110 epitaxially grows S/D features 800 in the S/D trenches 212 and over the protruding portions 202a of the semiconductor fins 215. The S/D features 800 may include n-type S/D features that correspond with n-type GAA transistor regions or p-type S/D features that correspond with p-type GAA transistor regions. The S/D features 800 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of the substrate 202 (or protruding portion 202a thereof) and/or semiconductor stack portions 214 (in particular, semiconductor layers 204a). Epitaxial S/D features 800 are doped with n-type dopants and/or p-type dopants. In some embodiments, for the n-type GAA transistors, epitaxial S/D features 800 include silicon and can be doped with carbon, phosphorous, arsenic, other n-type dopant, or combinations thereof (for example, forming Si: C epitaxial source/drain features, Si:P epitaxial source/drain features, or Si:C:P epitaxial source/drain features). In some embodiments, for the p-type GAA transistors, epitaxial S/D features 800 include silicon germanium or germanium and can be doped with boron, other p-type dopant, or combinations thereof (for example, forming Si:Ge:B epitaxial source/drain features).

In some embodiments, epitaxial S/D features 800 include materials and/or dopants that achieve desired tensile stress and/or compressive stress in respective channel regions CR. In some embodiments, epitaxial S/D features 800 are doped during deposition by adding impurities to a source material of the epitaxy process (i.e., in-situ). In some embodiments, epitaxial S/D features 800 are doped by an ion implantation process subsequent to a deposition process. In some embodiments, annealing processes (e.g., rapid thermal annealing (RTA) and/or laser annealing) are performed to activate dopants in epitaxial S/D features 800 and/or other source/drain regions (for example, heavily doped source/drain regions and/or lightly doped source/drain (LDD) regions). In some embodiments, epitaxial S/D features 800 are formed in separate processing sequences that include, for example, masking p-type GAA transistor regions when forming epitaxial S/D features 800 in n-type GAA transistor regions and masking n-type GAA transistor regions when forming epitaxial S/D features 800 in p-type GAA transistor regions.

In some embodiments (not shown), epitaxial S/D features 800 are formed to include more than one epitaxial layer. For example, e ach of the S/D features 800 includes an inner heavily doped layer and an outer lightly doped layer (or layers). In one embodiment, the outer lightly doped layer is first epitaxially grown in the S/D trenches 212 from side surfaces of the semiconductor layers 204a and the substrate 202. Then, the inner heavily doped layer is epitaxially grown from the outer lightly doped layer to fill the S/D trenches 212. The S/D features 800 may grow to a height above the topmost first semiconductor layers 204a and between gate spacers 211 of different dummy gate structures 208. As shown in FIG. 9B, the S/D features 800 are grown over the isolation structure 206.

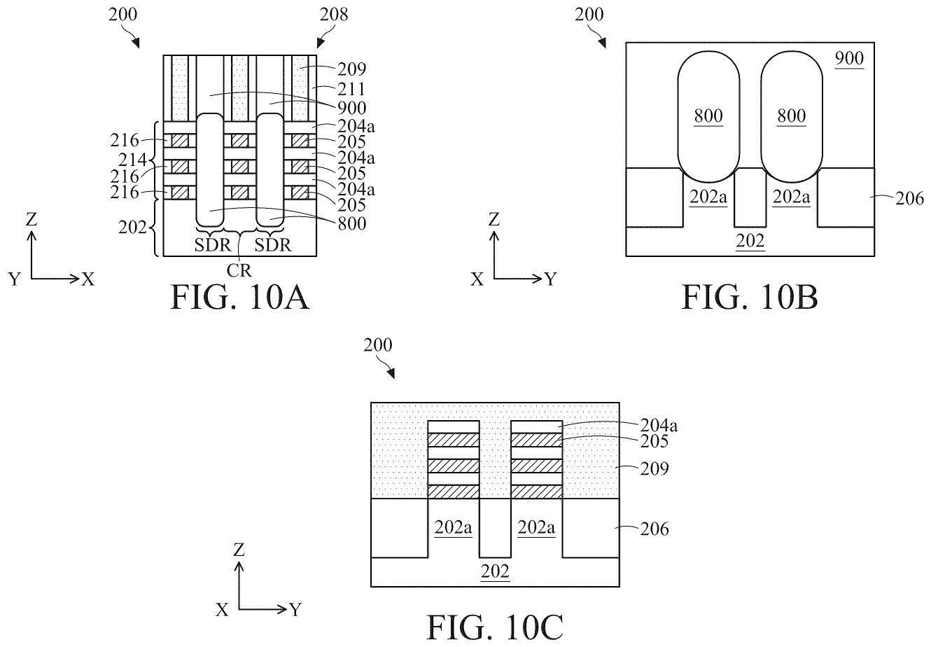

Referring now to FIGS. 10A-10C collectively, the method 100 at operation 112 forms an interlayer dielectric (ILD) layer 900 over the S/D features 800. As shown in FIG. 10A, the ILD layer 900 also fills the space between adjacent dummy gate structures 208. The ILD layer 900 may be formed by a deposition process (such as CVD, PVD, ALD, HDPCVD, MOCVD, RPCVD, PECVD, LPCVD, ALCVD, APCVD, plating, other suitable methods, or combinations thereof). In some embodiments, ILD layer 900 is formed by a flowable CVD (FCVD) process that includes, for example, depositing a flowable material (such as a liquid compound) over the device 200 and converting the flowable material to a solid material by a suitable technique, such as thermal annealing and/or ultraviolet radiation treating.

The ILD layer 900 includes a dielectric material including, for example, silicon oxide, silicon nitride, silicon oxynitride, TEOS formed oxide, PSG, BPSG, low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In the depicted embodiment, ILD layer 900 is a dielectric layer that includes a low-k dielectric material (generally referred to as a low-k dielectric layer). ILD layer 900 can include a multilayer structure having multiple dielectric materials. In some embodiments, a contact etch-stop layer (CESL) (not shown) is disposed between ILD layer 900 and the isolation structure 206, S/D features 800, and gate spacers 211. The CESL includes a material different than ILD layer 900, such as a dielectric material that is different than the dielectric material of ILD layer 900. For example, where ILD layer 900 includes silicon oxide or a low-k dielectric material, the CESL includes silicon and nitrogen, such as silicon nitride or silicon oxynitride. Subsequent to the deposition of ILD layer 900 and/or the CESL, a CMP process and/or other planarization process may be performed until reaching (exposing) a top portion (or top surface) of dummy gate stacks 209.

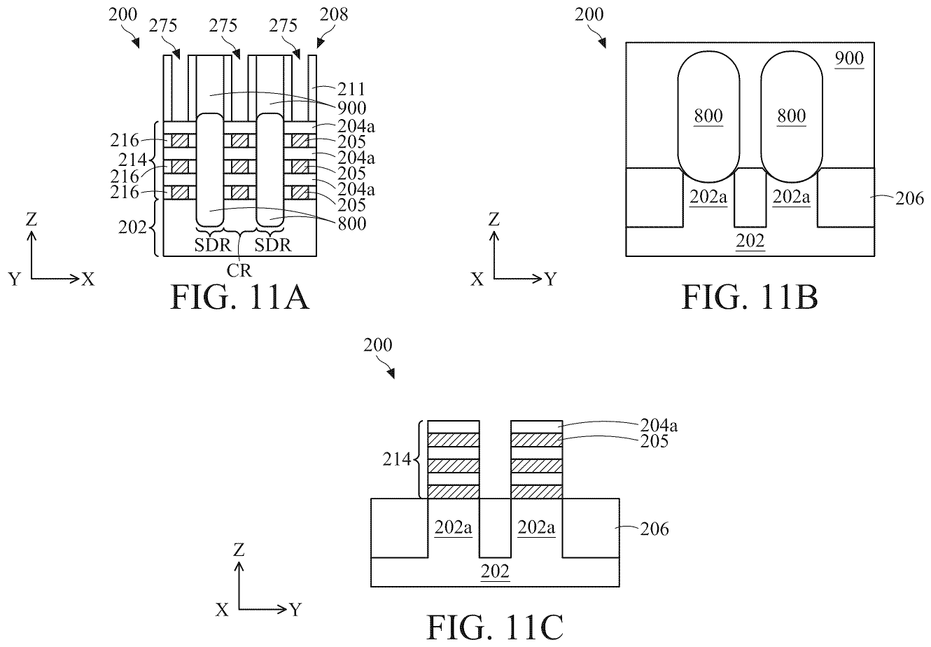

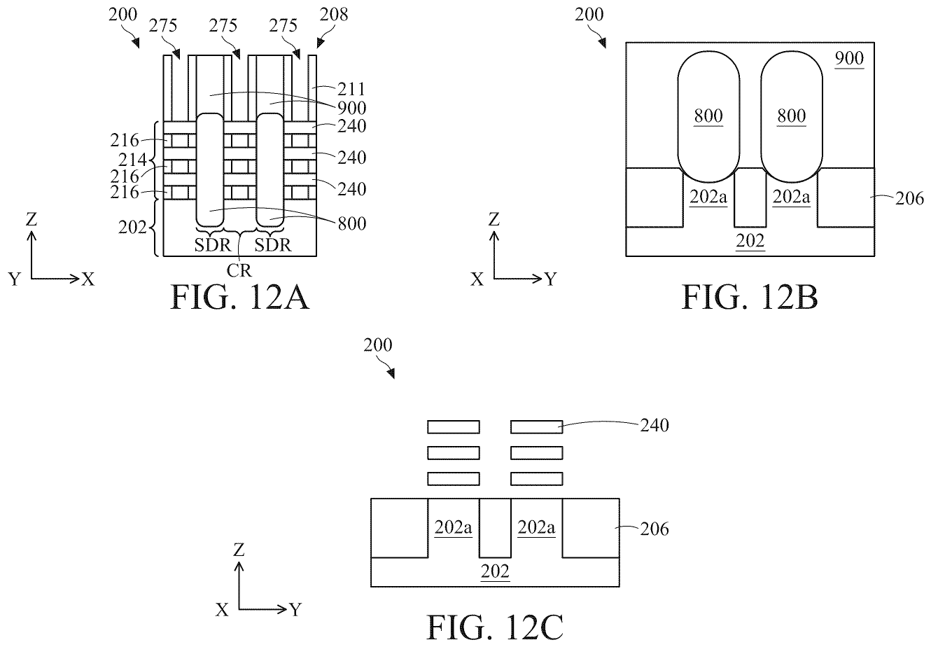

Referring now to FIGS. 11A-11C and 12A-12C collectively, the method 100 at operation 114 forms suspended semiconductor channels 240 by removing dummy gate stacks 209 from the dummy gate structures 208 and removing the interposer layers 205.

First, as shown in FIGS. 11A-11C, the operation 114 removes the dummy gate stacks 209 to expose the channel regions CR under the dummy gate stacks 209. The dummy gate stacks 209 are removed by a suitable etching process, thereby resulting in gate trenches 275 and exposing the semiconductor stack portions 214. The etching process is designed with etchant to selectively remove the dummy gate stacks 209. In the depicted embodiment, an etching process completely removes dummy gate stacks 209 to expose surfaces of the semiconductor layers 204a and interposer layers 205 in the y-z plane (see FIG. 11C). The etching process is a dry etching process, a wet etching process, other suitable etching process, or combinations thereof. In some embodiments, the etching process is a multi-step etch process. For example, the etching process may include alternative etchants to separately remove various layers of dummy gate stacks 209, such as dummy gate electrode layers, dummy gate dielectric layers, and/or dummy hard mask layers. In some embodiments, the etching process is configured to selectively etch dummy gate stacks 209 with minimal (to no) etching of other features of the device 200, such as ILD layer 900, gate spacers 211, semiconductor layers 204a, and interposer layers 205. In some embodiments, a lithography process is performed to form a patterned mask layer that covers ILD layer 900 and/or gate spacers 211, and the etching process uses the patterned mask layer as an etch mask.

Second, as shown in FIGS. 12A-12C, the interposer layers 205 (exposed by the gate trenches 275) are selectively removed from the channel regions CR, forming suspended semiconductor channels 240. In other words, what remains of the semiconductor layers 204a now become suspended semiconductor channels 240. This removal process is also known as channel-release, and this stage of the manufacturing process is referred to as the channel-release stage. In the depicted embodiment, an etching process selectively etches interposer layers 205 with minimal (to no) etching of semiconductor layers 204a and, in some embodiments, minimal (to no) etching of gate spacers 211 and/or inner spacers 216. Various etching parameters can be tuned to achieve selective etching of semiconductor layers 204b, such as etchant composition, etching temperature, etching solution concentration, etching time, etching pressure, source power, RF bias voltage, RF bias power, etchant flow rate, other suitable etching parameters, or combinations thereof. For example, an etchant is selected for the etching process that etches the material of interposer layer 205 (in the depicted embodiment, silicon oxide) at a higher rate than the material of semiconductor layers 204a (in the depicted embodiment, silicon) (i.e., the etchant has a high etch selectivity with respect to the material of interposer layers 205). The etching process is a dry etching process, a wet etching process, other suitable etching process, or combinations thereof.

As described previously, since the interposer layers 205 are etched at the channel-release stage (instead of the semiconductor layers 204b), the resulting suspended semiconductor channels 240 have a more square-shaped profile (e.g., with less than 50% curvature portions at its channel sidewalls). The suspended semiconductor channels 240 later becomes squared-shape channels 240, and the dimension details of the squared-shape channels 240 are later described with respect to FIGS. 15A-15B.

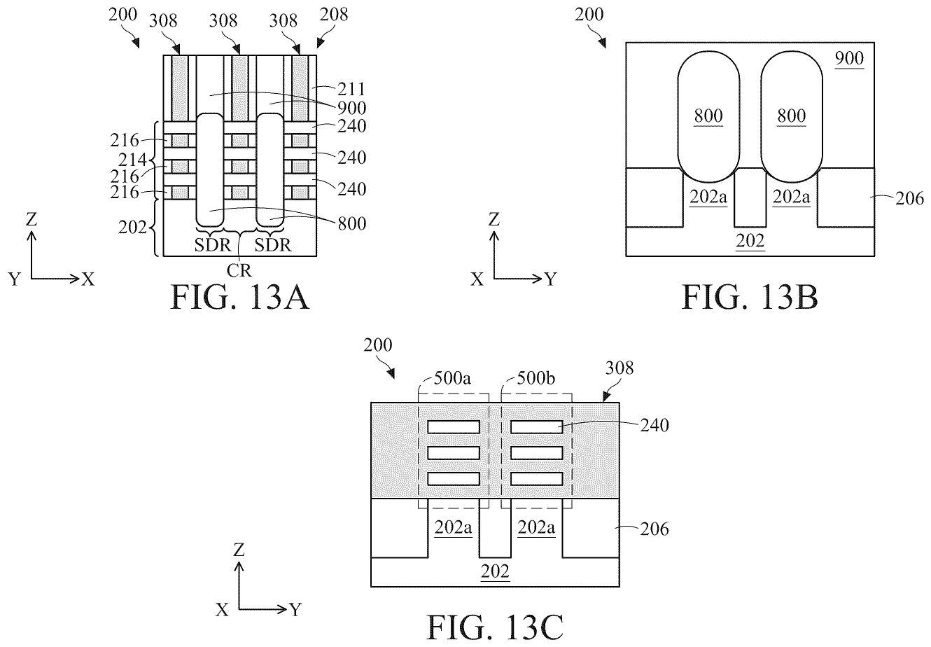

Referring now to FIGS. 13A-13C collectively, the method 100 at operation 116 forms metal gate structures 308 over the channel regions CR and wrapping around each of the suspended semiconductor channels 240. Although not shown in FIGS. 13A-13C (but shown in later figures), e ach of the metal gate structures 308 may include a gate dielectric layer and a gate electrode disposed on the gate dielectric layer. In some embodiments, the gate dielectric layer includes an interfacial layer and a high-k dielectric layer disposed on the interfacial layer. The gate electrode may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer includes a high-k dielectric material, such as materials having a dielectric constant greater than silicon oxide (k≈3.9). The gate electrodes may be formed by a CVD process or a PVD process that deposits a metal fill layer that fills remaining portions of the gate trenches 275 and over the gate dielectric layers. The metal fill layer includes a suitable conductive material, such as Al, W, and/or Cu. The metal fill layer may additionally or collectively include other metals, metal oxides, metal nitrides, other suitable materials, or combinations thereof. Alternatively, the metal fill layer is formed using another suitable deposition process, such as ALD, CVD, PVD, HDPCVD, MOCVD, RPCVD, PECVD, LPCVD, ALCVD, APCVD, spin coating, plating, other deposition process, or combinations thereof.

The method 100 may perform further steps to complete fabrication of the semiconductor device 200. For example, the method 100 further forms S/D contacts over the S/D features 800, gate contacts over the metal gate structure 308, and interconnect structures having interconnect metal lines and vias over the S/D and gate contacts. Additional operations can be provided before, during, and after method 100. Further, some of the operations described can be moved, replaced, or eliminated for additional embodiments of method 100.

As described in further detail below (see FIGS. 14A, 15A, and FIG. 16), the operation 116 may include forming the metal gate structures 308 to have thicker gate dielectric insulators wrapping around the channel corners of the square-shaped channels 240. This may provide added insulation for reducing parasitic electric fields at the channel rounded corners.

FIG. 13C illustrates a dashed box 500a containing a first stack of square-shaped channels 240 surrounded by a metal gate structure 308 and a dashed box 500b containing a second stack of square-shaped channels 240 surrounded by the metal gate structure 308. The first and second stacks are adjacent to each other and may share a common metal gate structure 308.

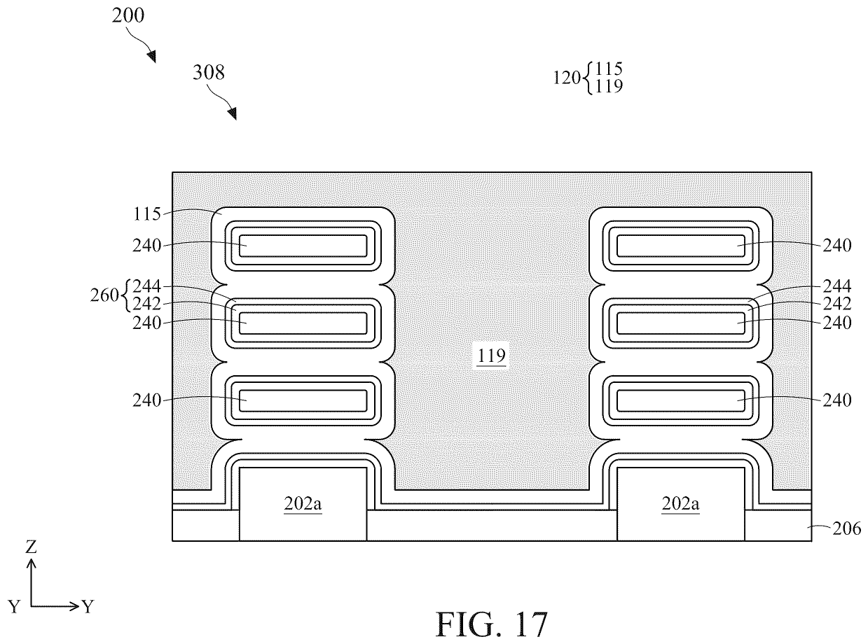

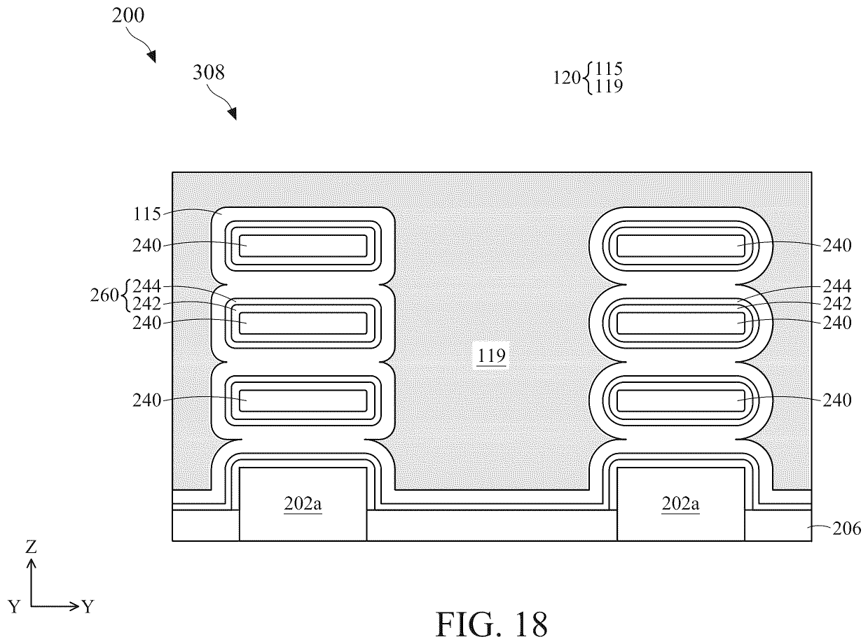

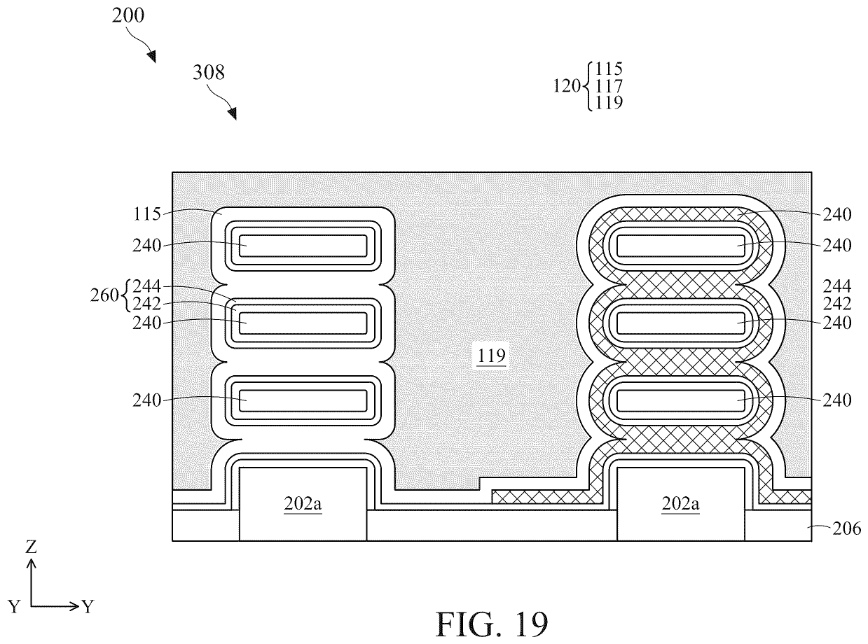

FIGS. 14A and 14B illustrate semiconductor devices (e.g., semiconductor device 200 or portions thereof) having square-shaped channels 240, according to different embodiments of the present disclosure. The semiconductor device in FIG. 14A may correspond to the region contained in the dashed box 500a, the dashed box 500b, or both the dashed box 500a and the dashed box 500b in FIG. 13C. The semiconductor device in FIG. 14B may correspond to one of the region contained in the dashed box 500a or the dashed box 500b in FIG. 13C. For example, both a first device in the dashed box 500a and a second device in the dashed box 500b correspond to a semiconductor device of FIG. 14A (as shown in FIG. 17). Alternatively, a first device in the dashed box 500a is the semiconductor device of FIG. 14A, a second device in the dashed box 500b is the semiconductor device of FIG. 14B, or vice versa (as shown in FIGS. 18 and 19). In an embodiment, the device of FIG. 14A is an n-type GAA FET, the device of FIG. 14B is a p-type GAA FET, or vice versa. In an embodiment, both the device of FIGS. 14A and 14B are n-type GAA FETs. In an embodiment, both the device of FIGS. 14A and 14B are p-type GAA FETs.

The semiconductor devices in FIGS. 14A and 14B are similar, each having square-shaped channels 240, and each channel 240 are surrounded by a metal gate structure 308. The channels 240 are made of a semiconductor material, including but not limited to Si, SiGe, Ge, GaAs, or InGaAs. The metal gate structure 308 includes a gate dielectric layer 260 wrapping around the square-shaped channels 240 and a gate electrode 120 disposed on and surrounding the gate dielectric layer 260. The gate dielectric layer 260 includes sublayers of gate dielectric insulators. These sublayers include an interfacial layer 242 wrapping around the channels 240 and a high-k dielectric layer 244 wrapping around the interfacial layer 242. The interfacial layer 242 may be an oxide-based dielectric, which may include but is not limited to SiOx, GeOx, SiGeOx, and its complex. In an embodiment, the interfacial layer 242 includes silicon oxide. The high-k dielectric layer 244 may include but is not limited to HfOx, ZrOx, LaOx, YOx, ScOx, AlOx, and its complex. In an embodiment, the high-k dielectric layer 244 includes hafnium oxide or zirconium oxide. Both the interfacial layer 242 and the high-k dielectric layer 244 can be doped or undoped. Possible dopants includes, but are not limited to, Si, La, Al, Y, Ge, Ga, Zn, N, F, Cl, C, and/or S. Although not explicitly shown, the gate electrode 120 may include several conductive layers, such as a capping layer, a work function metal layer, a blocking layer, a metal fill layer, and/or other proper conductive material layers.

The metal gate structure 308 is formed by first forming the gate dielectric layer 260 then depositing the gate electrode 120 over the gate dielectric layer 260. The gate dielectric layer 260 may be formed by first thermally growing an oxide over the square-shaped channels and over the protruding portion 202a of the substrate 202. The grown oxide forms the interfacial layer 242. Then, a high-k dielectric layer 244 is deposited over the interfacial layer 242. As shown, the high-k dielectric layer 244 not only wraps around portions of the interfacial layer 242 that surround channels 240, but it is also disposed over portions of the interfacial layer 242 on the protruding portion 202a of the substrate 202. Further, the high-k dielectric layer 244 may also be deposited over the isolation structure 206.

The difference between the devices in FIGS. 14A and 14B is in the shape of the gate dielectric layers 260. In FIG. 14A, the gate dielectric layer 260 is nonconformally deposited (or grown) over the square-shaped channels 240, such that the gate dielectric layer 260 is formed thicker at the corner portions of the square-shaped channels 240 than at non-corner portions of the square-shaped channels 240. Whereas in FIG. 14B, due to patterning loss, the gate dielectric layer 260 may be formed thinner at the corner portions of the square-shaped channels 240 than at non-corner portions of the square-shaped channels 240.

FIGS. 15A and 15B illustrate blown up views of specific regions in FIGS. 14A and 14B to illustrate further dimension details of the semiconductor devices of FIGS. 14A and 14B, respectively.

FIG. 15A illustrates a channel 240 in FIG. 14A nonconformally wrapped around by an interfacial layer 242 and by a high-k dielectric layer 244. The channel 240 has a total sheet height h1, and vertical sidewall portions (or flat sidewall portions) of the channel 240 have a height h2. The channel 240 further include curvature portions that define rounded corners of the channel 240. As described previously, the channel 240 has less than 50% curvature portions at its channel sidewalls. In other words, the vertical sidewall portions make up a majority of the channel sidewalls. In an embodiment, a percentage of the curvature portion to the total channel sheet height is equal to about 5% to less than 50% (i.e., (h1−h2)/h1 =˜5% to <50%). If the percentage is greater than 50%, the channels 240 are more rounded than they are squared, thereby introducing performance issues previously described. In an embodiment, the total sheet height h1 is equal to about 3 nm to about 15 nm.

Still referring to FIG. 15A, the interfacial layer 242 has a thickness t_{IL} around non-corner portions of the channel 240 and a thickness t_{IL′} around corner portions of the channel 240. The non-corner portions of the channel 240 refer to flat sheet portions (vertical and horizontal) of the channel 240. The thickness t_{IL′} is greater than the thickness t_{IL}. In an embodiment, the thickness t_{IL′} minus the thickness t_{IL} is equal to about 0.3 Å to about 0.5 Å. In an embodiment, the thickness t_{IL} ranges between about 3 Å to about 20 Å. In an embodiment, the thickness t_{IL′} ranges between about 3.3 Å to about 20.5 Å. In an embodiment, when the thickness t_{IL} is about 3 Å, the thickness t_{IL′} is about 3.3 Å to about 3.5 Å. In an embodiment, a ratio of t_{IL′} to t_{IL} ranges between about 1.05 to about 1.17.

Still referring to FIG. 15A, the high-k dielectric layer 244 has a thickness t_{HK} around non-corner portions of the channel 240 and a thickness t_{HK′} around corner portions of the channel 240. The thickness t_{HK′} is greater than the thickness t_{HK}. In other words, the high-k dielectric layer 244 has a thicker portion on the thicker portion (corner portion) of the interfacial layer 242 and a thinner portion on the thinner portion (non-corner portion) of the of the interfacial layer 242. In an embodiment, the thickness t_{HK′} minus the thickness t_{HK} is equal to about 0.3 Å to about 0.5 Å. In an embodiment, the thickness t_{HK} ranges between about 3 Å to about 20 Å. In an embodiment, the thickness t_{HK′} ranges between about 3.3 Å to about 20.5 Å. In an embodiment, when the thickness t_{HK} is about 3 Å, the thickness t_{HK′} is about 3.3 Å to about 3.5 Å. In an embodiment, a ratio of t_{HK′} to t_{HK} ranges between about 1.05 to about 1.17.

FIG. 15B is similar to FIG. 15A except that the thicknesses t_{IL′} and t_{HK′} are smaller than the respective thicknesses t_{IL} and t_{HK}. In other words, the gate dielectric layer 260 may be formed thinner at the corner portions of the square-shaped channels 240 than at non-corner portions of the square-shaped channels 240. This may be due to patterning loss as a result of extra exposure to patterning when forming different type FETs with a common metal gate structure 308 (i.e., dual metal gate flow causes extra patterning in a PFET or an NFET region that etch away corner portions of the gate dielectric layer 260).

Still referring to FIG. 15B, the thickness t_{IL′} is smaller than the thickness t_{IL}. In an embodiment, the thickness t_{IL′} minus the thickness t_{IL} is equal to about −0.3 Å to about −2 Å. In an embodiment, the thickness t_{IL} ranges between about 3 Å to about 20 Å. In an embodiment, the thickness t_{IL′} ranges between about 1 Å to about 19.7 Å. In an embodiment, when the thickness t_{IL} is about 3 Å, the thickness t_{IL′} is about 1 Å to about 2.7 Å. In an embodiment, a ratio of t_{IL′} to t_{IL} ranges between about 0.33 to about 0.98. The thickness t_{HK′} is smaller than the thickness t_{HK}. In an embodiment, the thickness t_{HK′} minus the thickness t_{HK} is equal to about −0.3 Å to about −2 Å. In an embodiment, the thickness t_{HK} ranges between about 3 Å to about 20 Å. In an embodiment, the thickness t_{HK′} ranges between about 1 Å to about 19.7 Å. In an embodiment, when the thickness t_{HK} is about 3 Å, the thickness t_{HK′} is about 1 Å to about 2.7 Å. In an embodiment, a ratio of t_{HK′} to t_{HK} ranges between about 0.33 to about 0.98.

FIG. 16 illustrates a flow chart of a method (e.g., operation 116) to form metal gate structures 308 with thicker gate dielectric insulators (e.g., gate dielectric layer 260) at transistor channel corners, in portion or in entirety, according to an embodiment of the present disclosure. For example, the operation 116 of method 100 may form the metal gate structure 308 shown in FIGS. 14A and 15A in accordance with the flow chart of FIG. 16. The operation 116 includes steps 1002-1012.

At step 1002, the operation 116 thermally grows an interfacial layer (e.g., interfacial layer 242) on the semiconductor channels 240. In the present embodiment, growing the interfacial layer includes thermally growing an oxide layer by introducing chemical gases (e.g., oxygen-containing and/or inert gases) over the semiconductor channels 240. To effectuate growing a thicker oxide around channel corners as opposed to the flat channel portions, the thermal operating temperature is carefully tuned. Experiments have shown that thermal oxide growth rates on (100) crystal surfaces and on (111) crystal surfaces converge as temperature increases. Specifically, at high temperatures (greater than 1000° C.), thermal oxide growth rates on (100) and (111) crystal surfaces converge to have similar or same growth rates. But at lower temperatures (less than 950° C.), the thermal growth rate on (111) crystal surfaces becomes greater than the thermal growth rate on (100) crystal surfaces. Since the corner portions of the channels 240 have (111) crystal surfaces and the flat sheet portions of the channels 240 have (100) crystal surfaces, growing the oxide layer at a lower temperature (less than 950° C.) allows the corner portions to grow at a higher rate than the flat sheet portions for desired profile. The oxide layer may be grown in a rapid thermal processing (RTP) process and results in the formation of the interfacial layer (e.g., interfacial layer 242) previously described. In an embodiment, oxygen is introduced intentionally and/or unintentionally at 0.02%˜100% [O]/N₂ at a pressure ranging between 1 torr to 25 atm pressure.

In an embodiment, the chemical gases introduced for growing the oxide layer include molecular base oxidant gases including O₂, O₃, H₂O, OH⁻, O⁻², and N₂O or a dilute gas with N₂ or other inert gases. In this case, an oxygen source is intentionally added as part of the thermal process. This may facilitate forming thicker interfacial layers, which in turn causes more pronounced thickness differences between channel corner portions and channel flat sheet portions. For this case, the target thermal growth temperature may range between about 500° C. to about 950° C., at a pressure ranging between about 1 torr to about 760 torr, for about 0 seconds to about 120 seconds. Alternatively, to facilitate more diverging growth rates between (100) and (111) crystal surfaces, a lower temperature is used, but the temperature is applied for a longer time and at a higher pressure. For example, the target temperature used for growing the oxide layer may range between about 250° C. to about 450° C., at a pressure ranging between about 700 torr to about 30 atm, for about 10 minutes to about 120 minutes.

In another embodiment, the chemical gases introduced for growing the oxide layer include N₂, Ar, He, or other inert gases. In this case, oxygen is not intentionally added but may be unintentionally introduced during previous processes or during N₂ or inert gas annealing. By not intentionally introducing oxygen, finer tuning of the interfacial layers may be possible. For this case, the target thermal growth temperature may range between about 500° C. to about 950° C., at a pressure ranging between about 1 torr to about 760 torr, for about 0 seconds to about 120 seconds. Alternatively, to facilitate more diverging growth rates between (100) and (111) crystal surfaces, a lower temperature is used, but the temperature is applied for a longer time and at a higher pressure. For example, the target temperature used for growing the oxide layer may range between about 250° C. to about 450° C., at a pressure ranging between about 700 torr to about 30 atm, for about 10 minutes to about 120 minutes.

In further embodiments, the chemical gases introduced for growing the oxide layer include radical base oxidant gases including O⁻², O₃, H₂O₂. Or the chemical gases introduced may be radical gases such as N₂, Ar, He, H₂ without intentional oxygen adding. In both these cases, the target temperature used for growing the oxide layer may range between room temperature (e.g., 25° C.) to about 600° C., at a pressure ranging between about 0.01 torr to about 10 torr, for about 5 seconds to about 300 seconds.

At step 1004, the operation 116, performs wet chemical cleaning, such as RCA clean to remove organic and/or ionic contaminants resulting from thermal oxidation. In an embodiment, the RCA clean includes a first cleaning step (SC-1) for organic cleaning and/or a second cleaning step (SC-2) for ionic cleaning. Chemicals used for cleaning may include ammonia water (NH₃), hydrogen peroxide (H₂O₂), hydrochloric acid (HCL), or combinations thereof. Notably, the wet chemical cleaning does not strip or substantially remove the oxide grown in operation 116. Even further, the wet chemical cleaning may also form a separate oxide layer due to reactions with certain cleaning chemicals (e.g., hydrogen peroxide). The oxide layer formed through wet chemical cleaning may be a conformal uniform layer. The separately formed oxide layer and the oxide layer formed through thermal growth, if both present, may collectively form a desired interfacial layer (e.g., the interfacial layer 242). Note that steps 1002 and 1004 may be recursively performed in a cyclic process until a desired oxide profile is formed with desired thicknesses and ratio of thicknesses for t_{IL} and t_{IL′} previously described. In an embodiment, the forming of interfacial layer (e.g., interfacial layer 242) includes thermal growth, wet chemical cleaning, or both, in a cyclic process. The cyclic process may include first steps 1002 that intentionally introduce oxygen and second steps 1002 that do not intentionally introduce oxygen. One or more steps 1004 may be performed between the first steps 1002 and the second steps 1002.

At step 1006, the operation 116 deposits a high-k dielectric layer (e.g., high-k dielectric layer 244) over the thermally grown interfacial layer (e.g., the interfacial layer 242) through atomic layer deposition (ALD). The high-k dielectric layer is deposited by sequentially and recursively applying a first precursor and then a second precursor to form a thin film surrounding the interfacial layer. The first precursor may be a metal-containing precursor and the second precursor may be an oxidant, or vice versa. Between applying the first and second precursors, a purge or evacuation step is performed to pump out gasses between each dose of the respective first and second precursors. In an embodiment, the high-k dielectric layer includes hafnium oxide (HfO₂) where the first precursor is one or more of HfCl₄, TEMA-Hf, or TDMA-Hf, and the second precursor is one or more of H₂O, H₂O₂, O₃, or O₂. In an embodiment, the high-k dielectric layer includes zirconium oxide (ZrO₂) where the first precursor is one or more of ZrCl₄, TEMA-Zr, or TDMA-Zr, and the second precursor is one or more of H₂O, H₂O₂, O₃, or O₂. To effectuate growing a thicker high-k dielectric around channel corners (over thicker portions of the interfacial layer) than around flat channel portions (over thinner portions of the interfacial layer), the ALD parameters are carefully tuned. Specifically, the high-k dielectric layer is deposited with nonconformal ALD parameters. To achieve this, in the present embodiment, the depositing of the high-k dielectric layer is carried out in a diffusion limited regime (as opposed to a reaction-limited regime) and the diffusion limited regime has a low diffusion coefficient, high reaction probability, and high aspect ratio. In a diffusion limited regime, the reactant molecules are already adsorbed before they have diffused all the way, while in a reaction-limited regime, the adsorption of gas-phase reaction molecules takes more time than the diffusion of these molecules. The diffusion limited regime may be defined by a Thiele modulus Φ that is much greater than 1. To effectuate this, the ALD parameters are tuned to have a high working pressure, a high precursor flow, a short precursor pulse time, or a combination thereof. For example, the working pressure of the ALD chamber during ALD growth is greater than about 5 torr such as between about 5 torr to about 100 torr; the precursor flow fraction between the precursors (first and second precursors) and the other gases (e.g., purge gases, carrier gases, etc.) is greater than about 35% such as between about 35% to about 70%; and/or the precursor pulse time of the first and/or the second precursors is shorter than about 1.5 seconds such as between about 0.1 to about 1.5 seconds.

At step 1008, the operation 116 performs thermal annealing to improve the surface topology and the electrical properties of the deposited high-k dielectric. Note that steps 1006 and 1008 may be recursively performed in a cyclic process until a desired high-k dielectric profile is formed with desired thicknesses and ratio of thicknesses for t_{HK} and t_{HK′} previously described. At the end of step 1008, a thermal insulator (e.g., gate dielectric layer 260) having thicker portions at channel portions is formed.

In an embodiment, step 1008 performs an annealing with intentional interfacial layer regrowth (e.g., regrowing interfacial layer 242). This may include introducing trace amounts of oxidizing agents or drive oxygen related species from by-products, surface capping layers, or adsorbed layers through thermal annealing. Step 1008 may be similar to step 1002 in terms of growth parameters and behaviors, and the similar parameters and behaviors are not described again for the sake of brevity. In further embodiments, step 1008 may include introducing nitridation gases (e.g., NH₃, N₂H₄), fluoridation gases (e.g., NF₃, F₂), radical base nitridation species (e.g., N*, NHₓ*), or radical fluoridation species (e.g., F*, FHₓ*) as part of thermal annealing. In cases where steps 1006 and 1008 are recursively performed in a cyclic process, the annealing steps between high-k dielectric deposition may include intentional interfacial layer regrowth while a last annealing step before step 1010 may be a normal annealing without intentional interfacial layer regrowth.

At step 1010, the operation 116 may form work function layers (see e.g., work function layers 115 and 117 in FIGS. 17-19) over the high-k dielectric layer (e.g., high-k dielectric layer 244). The work function layers may tune threshold voltages of different devices to tailor to design needs. As described previously, t he work function layers (if present) may be same or different and may be an n-type work function layer or a p-type work function layer, depending on the types of the corresponding GAA transistors. In an embodiment, the n-type work function layer includes aluminum and the p-type work function layer is free of aluminum (or has less aluminum than the n-type work function metal when both are present). In an embodiment, the n-type work function layer has less nitrogen than the p-type work function layer when both are present.

In some embodiments, the step 1010 is optional. For example, instead of forming work function layers to tune threshold voltages, dipole treatments may be performed to directly change the work functions of the deposited high-k dielectric for different devices. The dipole treatments may involve depositing n-doped or p-doped dipole layers for different devices, then thermally driving respective dopants of the dipole layers into respective high-k dielectric layers of the different devices. In some embodiments, the dipole layers may then be removed before step 1012 is performed.

At step 1012, the operation 116 may form a gate fill metal (see e.g., gate fill 119 in FIGS. 17-19) over the work function metals if present (see e.g., work function layers 115 and 117 in FIGS. 17-19). As described previously, the metal fill layer includes a suitable conductive material, such as Al, W, and/or Cu. The metal fill layer may additionally or collectively include other metals, metal oxides, metal nitrides, other suitable materials, or combinations thereof.

FIGS. 17-19 each illustrates a semiconductor device 200 having a first and a second GAA device having a shared metal gate structure 308, according to different embodiments of the present disclosure. In each of these embodiments, both the first and the second GAA devices have respective stacks of square-shaped channels 240 over protruding portions 202a of a substrate 202, gate dielectric layers 260 surrounding each the semiconductor channels 240, and a gate electrode 120 over the gate dielectric layers 260. The different embodiments shown in FIGS. 17-19 illustrate different device configurations according to design needs. Although it is generally desired for both a first and an adjacent second GAA device to have gate dielectric layers with thicker portions at channel corners, it may not always be possible. For example, due to patterning loss in multiple patterning cycles, over-etching due to patterning defects, and or other manufacturing cost concerns, an adjacent GAA device may result in gate dielectric layers with thinner portions at channel corners (e.g., see FIGS. 18 and 19) However, in all embodiments, at least one of two adjacent devices can achieve the thicker insulators at channel corners. Further, to tailor to performance needs, the device that require greater performance margins will be formed with the thicker insulators at channel corners while the device that do not require as much performance requirements may be tuned by other means such as specific work function metals (e.g., see FIG. 19).

Referring now to the embodiment shown in FIG. 17, each square-shaped channels 240 in the first and the second GAA devices include the gate dielectric layers 260 described with respect to FIGS. 14A-15A (i.e., thicker portions at channel corners). Each of the gate dielectric layers 260 is surrounded by and interfaces a same work function layer 115. The work function layer 115 may be a p-type work function layer for p-type GAA devices or a n-type work function layer for n-type GAA devices. A gate fill 119 is formed over the work function layer 115. In this embodiment, the work function layer 115 and the gate fill 119 collectively forms the gate electrode 120 disposed over the gate dielectric layers 260. In further embodiments, the gate electrode 120 include additional conductive layers.

Referring now to the embodiment shown in FIG. 18, the square-shaped channels 240 in a first GAA device include the gate dielectric layers 260 described with respect to FIGS. 14A-15A (i.e., thicker portions at channel corners), and the square-shaped channels 240 in a second GAA device include the gate dielectric layers 260 described with respect to FIGS. 14B-15B (i.e., thinner portions at channel corners). Each of the gate dielectric layers 260 is surrounded by and interfaces a same work function layer 115. The work function layer 115 may be a p-type work function layer for p-type GAA devices or a n-type work function layer for n-type GAA devices. A gate fill 119 is formed over the work function layer 115. In this embodiment, the work function layer 115 and the gate fill 119 collectively forms the gate electrode 120 disposed over the gate dielectric layers 260. In further embodiments, the gate electrode 120 includes additional conductive layers.

Referring now to the embodiment shown in FIG. 19, the square-shaped channels 240 in a first GAA device include the gate dielectric layers 260 described with respect to FIGS. 14A-15A (i.e., thicker portions at channel corners), and the square-shaped channels 240 in a second GAA device include the gate dielectric layers 260 described with respect to FIGS. 14B-15B (i.e., thinner portions at channel corners). In this embodiment, the gate dielectric layers 260 in the first and the second GAA devices interface different work function layers 115 and 117. The work function layer 115 surrounds and interface the gate dielectric layer 260 of a first GAA device, and the work function layer 117 surrounds and interface the gate dielectric layer 260 of a second GAA device. Note that the work function layer 115 may also be disposed over the work function layer 117 but is separated from the gate dielectric layer 260 of the second GAA device by the work function layer 117. The work function layer 115 and the work function layer 117 are opposite type work function layers. For example, the work function layer 115 may be a p-type work function layer for p-type GAA devices, the work function layer 117 may be an n-type work function layer for an n-type GAA devices, or vice versa. A gate fill 119 is formed over the work function layer 115. In this embodiment, the work function layer 115, the work function layer 117, and the gate fill 119 collectively forms the gate electrode 120 disposed over the gate dielectric layers 260. In further embodiments, the gate electrode 120 include additional conductive layers.

Although not limiting, the present disclosure offers advantages for GAA devices. One example advantage is to form the GAA devices with more square-shaped channels for performance boost. Another example advantage is to form nonconformal interfacial layers with selective thicker portions to alleviate extraneous electric fields at channel rounded corners. Another example advantage is to form nonconformal high-k dielectric layers around the interfacial layers with selective thicker portions to further alleviate extraneous electric fields at channel rounded corners. Another example advantage is to selectively form the nonconformal gate dielectric layers in cases of shared gate structures according to design needs.

One aspect of the present disclosure pertains to a method of forming a semiconductor device. The method includes forming a stack of semiconductor channels over a semiconductor fin, wherein each of the semiconductor channels are squared-shaped with rounded corners, and the rounded corners interface between vertical and horizontal surfaces of the semiconductor channels; forming a nonconformal interfacial layer over and wrapping around each semiconductor channel of the stack of semiconductor channels, wherein the interfacial layer has a thicker portion at corner portions of the semiconductor channels and a thinner portion at non-corner portions of the semiconductor channels; forming a nonconformal high-k dielectric layer over and wrapping around the nonconformal interfacial layer, wherein the high-k dielectric layer has a thicker portion on the thicker portion of the interfacial layer and a thinner portion on the thinner portion of the of the interfacial layer; and forming a gate electrode over the high-k dielectric layer.

In an embodiment, the semiconductor channels are formed to have channel sidewalls that have vertical sidewall portions and rounded corner portions, wherein there is a greater percentage of the vertical sidewall portions than that of the rounded corner portions. In a further embodiment, the percentage of the rounded corner portions range between about 5% to about 50% of the channel sidewalls.

In an embodiment, the forming of the nonconformal interfacial layer includes thermally growing an oxide on each semiconductor channel of the stack of semiconductor channels. In a further embodiment, the oxide is grown at a temperature between about 500° C. to about 950° C. In a further embodiment, the oxide is grown by introducing oxygen at 0.02%˜100% [O]/N2 at a pressure ranging between 1 torr to 25 atm pressure.

In an embodiment, the forming of the nonconformal high-k dielectric layer includes depositing a high-k dielectric through atomic layer deposition (ALD). In a further embodiment, the high-k dielectric is hafnium oxide deposited by sequentially applying a first precursor and a second precursor, the first precursor is one or more of HfCl4, TEMA-Hf, or TDMA-Hf, and the second precursor is one or more of H2O, H2O2, O3, or O2. In a further embodiment, the high-k dielectric is deposited by a diffusion limited regime.

Another aspect of the present disclosure pertains to a method of forming a semiconductor device. The method includes first thermally growing an oxide over and wrapping around a semiconductor channel; perform wet chemical cleaning to remove contaminants resulting from the first thermally growing; second thermally growing the oxide to form an interfacial layer; depositing a high-k dielectric material over the interfacial layer by atomic layer deposition (ALD); and thermal annealing the high-k dielectric material to form a high-k dielectric layer. The interfacial layer and the high-k dielectric layer collectively forms a gate dielectric layer, where the gate dielectric layer is formed to have a thicker portion at corner portions of the semiconductor channel and a thinner portion at non-corner portions of the semiconductor channel.

In an embodiment, the interfacial layer is formed to have a thicker portion at the corner portions of the semiconductor channel and a thinner portion at the non-corner portions of the semiconductor channel.

In an embodiment, the high-k dielectric layer is formed to have a thicker portion around the corner portions of the semiconductor channel and a thinner portion around the non-corner portions of the semiconductor channel.

In an embodiment, after the thermal annealing of the high-k dielectric material, the method further includes depositing a second high-k dielectric material over the high-k dielectric material; and thermal annealing the second high-k dielectric material and the high-k dielectric material to form the high-k dielectric layer.

In an embodiment, the first thermally growing includes growing the oxide at a temperature between about 500° C. to about 950° C.

In an embodiment, the depositing the high-k dielectric material includes depositing the high-k dielectric material in a diffusion limited regime such that a Thiele modulus Φ is much greater than 1.

Another aspect of the present disclosure pertains to a semiconductor device. The semiconductor device includes a stack of semiconductor channels over a substrate, where at least one semiconductor channel of the stack includes channel sidewalls defined by vertical portions and rounded corner portions, where the vertical portions make up a majority of the channel sidewalls; an interfacial layer wrapping around each semiconductor channel of the stack of semiconductor channels, wherein the interfacial layer has a thicker portion at corner portions of the semiconductor channel and a thinner portion at non-corner portions of the semiconductor channels; a high-k dielectric layer over and wrapping around the interfacial layer, where the high-k dielectric layer has a thicker portion on the thicker portion of the interfacial layer and a thinner portion on the thinner portion of the of the interfacial layer; and a gate electrode over the high-k dielectric layer.

In an embodiment, the thinner portion of the interfacial layer ranges between about 3 Å to about 20 Å.

In an embodiment, a thickness difference between the thicker portion of the interfacial layer and the thinner portion of the interfacial layer ranges between about 0.3 Å to about 0.5 Å.

In an embodiment, the thinner portion of the high-k dielectric layer ranges between about 3 Å to about 20 Å.

In an embodiment, a thickness difference between the thicker portion of the high-k dielectric layer and the thinner portion of the high-k dielectric layer ranges between about 0.3 Å to about 0.5 Å.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a stack of semiconductor channels over a semiconductor fin, wherein each of the semiconductor channels are squared-shaped with rounded corners, and the rounded corners interface between vertical and horizontal surfaces of the semiconductor channels;
forming a nonconformal interfacial layer over and wrapping around each semiconductor channel of the stack of semiconductor channels, wherein the interfacial layer has a thicker portion at corner portions of the semiconductor channels and a thinner portion at non-corner portions of the semiconductor channels;
forming a nonconformal high-k dielectric layer over and wrapping around the nonconformal interfacial layer, wherein the high-k dielectric layer has a thicker portion on the thicker portion of the interfacial layer and a thinner portion on the thinner portion of the of the interfacial layer; and
forming a gate electrode over the high-k dielectric layer.

2. The method of claim 1, wherein the semiconductor channels are formed to have channel sidewalls that have vertical sidewall portions and rounded corner portions, wherein there is a greater percentage of the vertical sidewall portions than that of the rounded corner portions.

3. The method of claim 2, wherein the percentage of the rounded corner portions range between about 5% to about 50% of the channel sidewalls.

4. The method of claim 1, wherein the forming of the nonconformal interfacial layer includes thermally growing an oxide on each semiconductor channel of the stack of semiconductor channels.

5. The method of claim 4, wherein the oxide is grown at a temperature between about 500°C to about 950°C.

6. The method of claim 4, wherein the oxide is grown by introducing oxygen at 0.02%˜100% [O]/N2 at a pressure ranging between 1 torr to 25 atm pressure.

7. The method of claim 1, wherein the forming of the nonconformal high-k dielectric layer includes depositing a high-k dielectric through atomic layer deposition (ALD).

8. The method of claim 7, wherein the high-k dielectric is hafnium oxide deposited by sequentially applying a first precursor and a second precursor, the first precursor is one or more of HfCl₄, TEMA-Hf, or TDMA-Hf, and the second precursor is one or more of H₂O, H₂O₂, O₃, or O₂.

9. The method of claim 7, wherein the high-k dielectric is deposited by a diffusion limited regime.

10. A method of forming a semiconductor device, comprising:
first thermally growing an oxide over and wrapping around a semiconductor channel;
perform wet chemical cleaning to remove contaminants resulting from the first thermally growing;
second thermally growing the oxide to form an interfacial layer;
depositing a high-k dielectric material over the interfacial layer by atomic layer deposition (ALD); and
thermal annealing the high-k dielectric material to form a high-k dielectric layer,
wherein the interfacial layer and the high-k dielectric layer collectively forms a gate dielectric layer,
wherein the gate dielectric layer is formed to have a thicker portion at corner portions of the semiconductor channel and a thinner portion at non-corner portions of the semiconductor channel.

11. The method of claim 10, wherein the interfacial layer is formed to have a thicker portion at the corner portions of the semiconductor channel and a thinner portion at the non-corner portions of the semiconductor channel.

12. The method of claim 10, wherein the high-k dielectric layer is formed to have a thicker portion around the corner portions of the semiconductor channel and a thinner portion around the non-corner portions of the semiconductor channel.

13. The method of claim 10, wherein after the thermal annealing of the high-k dielectric material, further comprising:
depositing a second high-k dielectric material over the high-k dielectric material; and
thermal annealing the second high-k dielectric material and the high-k dielectric material to form the high-k dielectric layer.

14. The method of claim 10, wherein the first thermally growing includes growing the oxide at a temperature between about 500°C to about 950°C.

15. The method of claim 10, wherein the depositing the high-k dielectric material includes depositing the high-k dielectric material in a diffusion limited regime such that a Thiele modulus Φ is much greater than 1.

16. A semiconductor device, comprising:
a stack of semiconductor channels over a substrate, wherein at least one semiconductor channel of the stack includes channel sidewalls defined by vertical portions and rounded corner portions, wherein the vertical portions make up a majority of the channel sidewalls;
an interfacial layer wrapping around each semiconductor channel of the stack of semiconductor channels, wherein the interfacial layer has a thicker portion at corner portions of the semiconductor channel and a thinner portion at non-corner portions of the semiconductor channels;
a high-k dielectric layer over and wrapping around the interfacial layer, wherein the high-k dielectric layer has a thicker portion on the thicker portion of the interfacial layer and a thinner portion on the thinner portion of the of the interfacial layer; and
a gate electrode over the high-k dielectric layer.

17. The semiconductor device of claim 16, wherein the thinner portion of the interfacial layer ranges between about 3 Å to about 20 Å.

18. The semiconductor device of claim 16, wherein a thickness difference between the thicker portion of the interfacial layer and the thinner portion of the interfacial layer ranges between about 0.3 Å to about 0.5 Å.

19. The semiconductor device of claim 16, wherein the thinner portion of the high-k dielectric layer ranges between about 3 Å to about 20 Å.

20. The semiconductor device of claim 16, wherein a thickness difference between the thicker portion of the high-k dielectric layer and the thinner portion of the high-k dielectric layer ranges between about 0.3 Å to about 0.5 Å.
